(19) United States
(12) Patent Application Publication
(10) Pub. No.: US 2021/0092798 A1
(43) Pub. Date: Mar. 25, 2021

(54) Substrate Processing Apparatus and Gas Box

(71) Applicant: Kokusai Electric Corporation, Tokyo (JP)

(72) Inventors: Kazuya NABETA, Toyama (JP); Motoya TAKEWAKI, Toyama (JP)

(21) Appl. No.: 17/024,249

(22) Filed: Sep. 17, 2020

(30) Foreign Application Priority Data
Sep. 25, 2019 (JP) 2019-174571

(51) Int. Cl. H05B 1/02; B05C 11/10

(52) U.S. Cl. CPC H05B 1/0244; B05C 11/1015; H05B 1/0233

(57) ABSTRACT

Described herein is a technique capable of preventing a deterioration in controllability of a gas flow rate in a substrate processing apparatus. According to one aspect thereof a substrate processing apparatus includes: a process furnace including a process chamber; a process gas supply path; a process gas supply controller; a heater configured to heat at least a part of the process gas supply controller or the process gas supply path; a gas box accommodating the process gas supply path, the process gas supply controller and the heater. The gas box includes: an inlet port configured to introduce an outer atmosphere; an exhaust port connected to an exhaust duct and configured to exhaust an inner atmosphere to the exhaust duct; a temperature controller configured to lower and monitor a temperature of the inner atmosphere; and a gas leakage sensor configured to detect the process gas leaked in the gas box.

### CROSS REFERENCE TO RELATED APPLICATIONS

This application claims foreign priority under 35 U.S.C. § 119(a)-(d) to Application No. JP 2019-174571 filed on Sep. 25, 2019, the entire contents of which are hereby incorporated by reference.

### TECHNICAL FIELD

The present disclosure relates to a substrate processing apparatus and a gas box.

### BACKGROUND

In manufacturing processes of a device such as a semiconductor device (for example, an integrated circuit), a substrate processing apparatus configured to perform a heat treatment process such as a film-forming process, an oxidation process, a diffusion process and an annealing process on a substrate such as a silicon wafer may be widely used. The substrate processing apparatus describe above includes a gas supply system configured to supply a process gas into a process chamber of the substrate processing apparatus. The gas supply system is accommodated in an enclosure in order to prevent a leaked gas, such as a leaked process gas, from being exposed to people. The enclosure may also be referred to as a “gas box”. The gas box is connected to an exhaust duct which is maintained under a negative pressure, and ventilated.

A liquid source which is in a liquid state at room temperature may be heated and vaporized by a vaporizer and supplied into the process chamber as the process gas. When the process gas is supplied, a pipe (or pipes) through which the process gas is supplied may be heated in order to prevent a re-liquefaction of the vaporized liquid source.

An MFC (mass flow controller) including an electric circuit and configured to control a flow rate of the process gas may be accommodated in the gas box as a part of the gas supply system. When the number of the pipes to be heated is increased for the reasons such as the use of the liquid source or when a large object to be heated is placed in the gas box, the heat exhaust may be delayed. Therefore, an inner temperature of the gas box (also referred to as an “MFC environmental temperature”) may be further elevated. When the inner temperature of the gas box is maintained high or elevated or lowered, a controllability of the gas flow rate may be deteriorated due to the characteristics of components provided in the gas box so that a quality of the substrate processed by the substrate processing apparatus may become unsatisfactory as a product.

### SUMMARY

Described herein is a technique capable of preventing a deterioration in controllability of a gas flow rate in a substrate processing apparatus.

According to one aspect of the technique of the present disclosure, there is provided a substrate processing apparatus including: a process furnace including a process chamber in which a substrate is processed; a process gas supply path configured to supply a process gas of processing the substrate into the process chamber; a process gas supply controller configured to control an amount of the process gas supplied into the process chamber; a heater configured to heat at least a part of the process gas supply controller or the process gas supply path; a gas box configured to accommodate the process gas supply path, the process gas supply controller and the heater; wherein the gas box includes: an inlet port configured to introduce an outer atmosphere of the gas box into the gas box; an exhaust port connected to an exhaust duct and configured to exhaust an inner atmosphere of the gas box to the exhaust duct; a temperature controller configured to cool the inner atmosphere of the gas box and to detect and monitor a temperature of the inner atmosphere of the gas box; and a gas leakage sensor configured to detect a leakage of the process gas.

### BRIEF DESCRIPTION OF THE DRAWINGS

FIG. 1 is a perspective view schematically illustrating a substrate processing apparatus according to one or more embodiments described herein.

FIG. 2 schematically illustrates a vertical cross-section of the substrate processing apparatus according to the embodiments described herein.

FIG. 3 schematically illustrates a vertical cross-section of a gas box of the substrate processing apparatus according to the embodiments described herein.

FIG. 4 is a block diagram schematically illustrating a main controller and related components of the substrate processing apparatus according to the embodiments described herein.

FIG. 5 is a flow chart schematically illustrating a processing related to a temperature control of the gas box according to the embodiments described herein.

FIG. 6 schematically illustrates a vertical cross-section of a gas box of the substrate processing apparatus according to a modified example of the embodiments described herein.

### DETAILED DESCRIPTION

Hereinafter, one or more embodiments (also simply referred to as “embodiments”) according to the technique of the present disclosure will be described with reference to the drawings.

### Embodiment

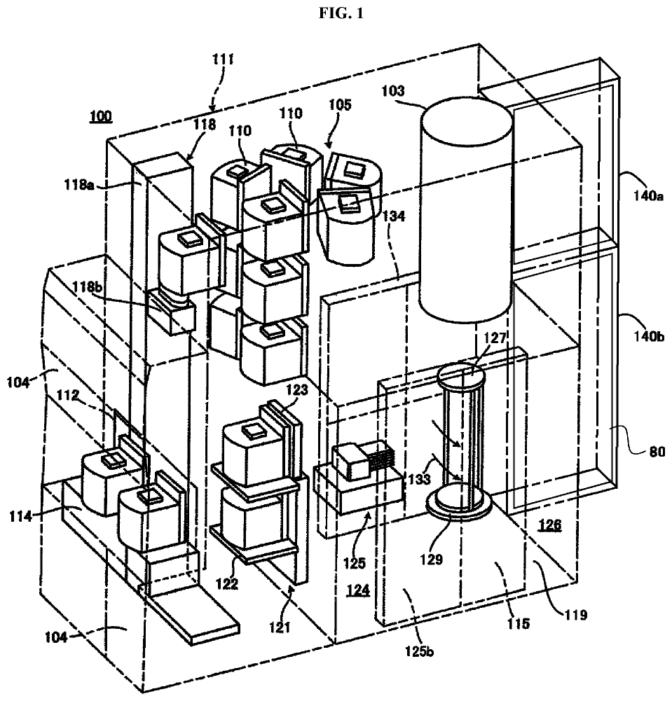

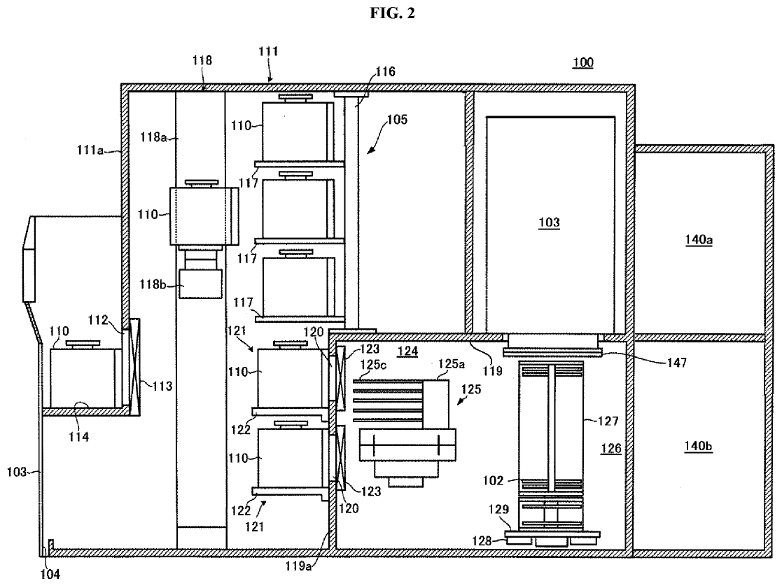

For example, in the embodiments according to the technique of the present disclosure, a substrate processing apparatus is configured as a semiconductor manufacturing apparatus that performs a substrate processing. The substrate processing is performed as a part of manufacturing processes in a method of manufacturing a semiconductor device (for example, an integrated circuit). In the following description, for example, a batch apparatus that performs a CVD (Chemical Vapor Deposition) process is assumed to be used as the substrate processing apparatus. FIG. 1 is an oblique perspective view schematically illustrating the substrate processing apparatus according to the present embodiment, and FIG. 2 schematically illustrates a vertical cross-section of the substrate processing apparatus according to the present embodiment shown in FIG. 1.

As shown in FIGS. 1 and 2, a substrate processing apparatus 100 according to the present embodiment is configured to process a plurality of wafers including a wafer 102 transferred into a process furnace 103. The plurality of the wafers are loaded into the process furnace 103 using a pod 110 such as a FOUP (front opening unified pod) capable of accommodating wafers including the wafer 102, and are processed in the process furnace 103. The pod 110 may also be referred to as a “substrate container” or a “wafer carrier”. A pod loading/unloading port (also referred to as a “substrate container loading/unloading port”) 112 is provided at a front wall 111a of a housing 111 of the substrate processing apparatus 100 so as to communicate with an inside and an outside of the housing 111. The pod loading/unloading port 112 may be opened or closed by a front shutter (also referred to as a “substrate container loading/unloading port opening/closing structure”) 113. A loading port (also referred to as a “substrate container loading/unloading table”) 114 is provided at a front side of the pod loading/unloading port 112. The loading port 114 is configured such that the pod 110 is aligned while placed on the loading port 114. The pod 110 is transferred onto and out of the loading port 114 by an in-process transfer device (not shown).

A rotatable pod shelf (also referred to as a “substrate container placement shelf”) 105 is provided at an upper part of an approximately and horizontally central portion in a front-rear direction of the housing 111. The rotatable pod shelf 105 is configured to store a plurality of pods including the pod 110 (also simply referred to as “pods 110”). The rotatable pod shelf 105 includes a vertical column 116 capable of rotating horizontally and a plurality of shelf plates (also simply referred to as “shelf plates”) 117 radially fixed to the vertical column 116 at upper, middle and lower locations thereof. The shelf plates 117 may also be referred to as “substrate container placement plates”. The shelf plates 117 are configured to support the pods 110 while the pods 110 are placed thereon. According to the present embodiment, for example, 15 pods can be placed on the shelf plates 117 as the pods 110. However, the illustrations of some of the pods 110 are omitted in FIG. 1 for convenience.

A pod transfer device (also referred to as a “substrate container transfer device”) 118 is provided between the loading port 114 and the rotatable pod shelf 105 in the housing 111. The pod transfer device 118 is constituted by a pod elevator (also referred to as a “substrate container elevator”) 118a capable of elevating or lowering the pod 110 while the pod 110 is placed thereon and a pod transfer structure (also referred to as a “substrate container transfer structure”) 118b serving as a transfer structure. The pod transfer device 118 is configured to transfer the pod 110 among the loading port 114, the rotatable pod shelf 105 and a pod opener (also referred to as a “substrate container opener/closer”) 121 described later by consecutive operations of the pod elevator 118a and the pod transfer structure 118b.

A sub-housing 119 defining a loading chamber 124 is provided at a lower part of an approximately and horizontally central portion in the front-rear direction in the housing 111 to contact a rear end of the substrate processing apparatus 100. The loading chamber 124 may also be referred to as a “loading region” or a “transfer chamber” 124. A pair of wafer loading/unloading ports (also referred to as “substrate loading/unloading ports”) 120 are provided at a front wall 119a of the sub-housing 119 to be arranged vertically in two stages. That is, an upper wafer loading/unloading port and a lower wafer loading/unloading port are provided as the pair of the wafer loading/unloading ports 120. The wafer 102 may be loaded into or unloaded out of the sub-housing 119 through the pair of the wafer loading/unloading ports 120. A pair of pod openers including the pod opener 121 is provided at the pair of the wafer loading/unloading ports 120, respectively. For example, an upper pod opener and a lower pod opener may be provided as the pair of the pod openers. The upper pod opener and the lower pod opener may be individually referred to as the “pod opener 121”. The pod opener 121 includes a placement table 122 where the pod 110 is placed thereon and a cap attaching/detaching structure (also referred to as a “lid attaching/detaching structure”) 123 configured to attach or detach a cap (which is a lid) of the pod 110. By detaching or attaching the cap of the pod 110 placed on the placement table 122 by the pod opener 121, a wafer entrance of the pod 110 is opened or closed.

The loading chamber 124 is fluidically isolated from an installation space in which the pod transfer device 118 or the rotatable pod shelf 105 is provided, or an inner pressure of the loading chamber 124 is maintained at a pressure (positive pressure) higher than that of the installation space so that a fluid flows in a single direction. A wafer transfer device (also referred to as a “substrate transfer device”) 125 is provided in a front region of the loading chamber 124. The wafer transfer device 125 is constituted by a wafer transfer structure (also referred to as a “substrate transfer structure”) 125a, a wafer transfer structure elevator (also referred to as a “substrate transfer structure elevator”) 125b and tweezers 125c. The wafer transfer structure 125a is configured to support the wafer 102 by the tweezers 125c and to rotate or move the wafer 102 horizontally. The wafer transfer structure elevator 125b is configured to elevate or lower the wafer transfer structure 125a. The wafer transfer structure elevator 125b is provided on a right side surface in the sub-housing 119 along the vertical direction. The wafer transfer device 125 may load or unload the wafer 102 into or out of a boat (also referred to as a “substrate retainer”) 127 by operations of the wafer transfer structure elevator 125b and the wafer transfer structure 125a while the wafer 102 is placed on and supported by the tweezers (also referred to as a “substrate holder”) 125c.

A standby region 126 in which the boat 127 is accommodated in standby is provided at a rear side of the transfer chamber 124. The process furnace 103 is provided above the standby region 126 with a furnace opening of the process furnace 103 facing down. The furnace opening of the process furnace 103 is opened and closed by a furnace opening shutter (also be referred to as a “furnace opening/closing structure”) 147.

A boat elevator (also referred to as a “substrate retainer elevator”) 115 is provided on a right side surface of the standby region 126 in the sub-housing 119, and is configured to elevate or lower the boat 127. An arm 128 is connected to an elevating table of the boat elevator 115. A seal cap 129 serving as a lid of the furnace opening is provided horizontally at the arm 128. The seal cap 129 is configured to support the boat 127 vertically and to close a lower end portion of the process furnace 103. The boat 127 includes a plurality of support columns (also referred to as “supports”) (not shown). The boat 127 is configured to support the plurality of the wafers (for example, 50 to 125 wafers) including the wafer 102 horizontally with their centers aligned concentrically in vertical direction.

A clean air supply structure 134 is provided on a left side surface in the transfer chamber 124. The clean air supply structure 134 is configured to supply clean air 133 such as a clean atmosphere and an inert gas into the transfer chamber 124. The clean air supply structure 134 includes a supply fan (not shown) and a dust-proof filter (not shown). A notch alignment device (not shown) serving as a substrate alignment device configured to align a circumferential position of the wafer 102 may be provided in the transfer chamber 124. The clean air 133 ejected from the clean air supply structure 134 flows around the notch alignment device, the wafer transfer structure 125a and the boat 127 in the standby region 126. Thereafter, the clean air 133 is introduced through an inlet port (not shown) provided along the wafer transfer structure elevator 125b or the boat elevator 115, and then is exhausted out of the housing 111. Alternatively, the clean air 133 introduced through the inlet port may be circulated back to a primary side (supply side) of the clean air supply structure 134, and then ejected again into the transfer chamber 124 by the clean air supply structure 134.

Each of gas boxes 140a and 140b (that is, an upper gas box 140a and a lower gas box 140b) is of a cuboid shape that is elongated in the vertical and front-rear directions, and is provided on a rear surface of the housing 111 so that one side surface of the gas boxes 140a and 140b is continuously connected with a side surface of the housing 111. Each of the gas boxes 140a and 140b is configured to accommodate the gas supply system. A maintenance door 80 configured to open or close the gas boxes 140a and 140b is provided on another side surface of the gas boxes 140a and 140b so as to maintain the gas supply system. In the present specification, the maintenance door 80 may also be referred to as an opening/closing door of the gas box. Hereinafter, the side surface of the gas boxes 140a and 140b provided with the maintenance door 80 may also be referred to as a front surface of the gas boxes 140a and 140b. A front panel 75 includes the maintenance door 80 and is located at the front surface of the gas boxes 140a and 140b. The upper gas box 140a is configured to accommodate components such as a gas supply structure of a source in a gaseous state or a carrier gas and a final valve, and the lower gas box 140b is configured to accommodate components such as a tank of a liquid source (that is, a source in a liquid state), a vaporizer and flow rate controllers thereof. Hereinafter, the upper gas box 140a may also be referred to as the gas box 140a, and the lower gas box 140b may also be referred to as the gas box 140b. The gas box 140b may serve as a process gas supply source for the gas box 140a.

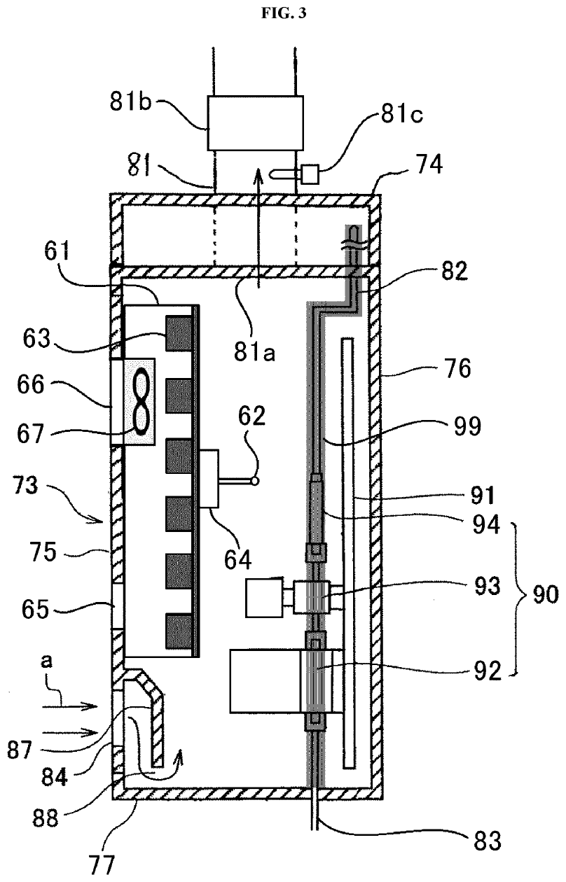

Hereinafter, an internal configuration of the gas box 140a will be described as a representative example of the gas boxes 140a and 140b. As shown in FIG. 3, the gas box 140a includes a box housing 73 serving as a casing that covers each of the side surfaces of the gas box 140a. An exhaust port 81a connected to an exhaust duct 81 and configured to exhaust an inner atmosphere (air) of the box housing 73 (that is, the gas box 140a) is provided on an upper surface 74 of the box housing 73. In addition, an inlet port 84 configured to introduce an outer atmosphere (for example, the air) of the box housing 73 into the box housing 73 is provided at a lower portion of the front panel 75. The outer atmosphere of the box housing 73 (for example, the air outside the gas box 140a) serves as a low temperature source when cooling the gas box 140a. The exhaust duct 81 is connected by a flexible duct made of a material such as stainless steel so that an exhaust gas such as the process gas is exhausted to a processing system exhaust gas path provided in a clean room other than the substrate processing apparatus 100. A manual damper valve 81b configured to adjust an exhaust flow rate of the exhaust gas and a gas sensor (also referred to as a “gas leakage sensor”) 81c configured to detect a leaked gas such as a leaked process gas are provided in the middle of the exhaust duct 81.

Provided in the gas box 140a are: a first pipe 82 serving as a first process gas supply path configured to supply the process gas of processing the wafer 102 into a process chamber (not shown) in the process furnace 103 via a process gas supply controller 90; a second pipe 83 serving as a second process gas supply path configured to supply the process gas to the process gas supply controller 90; and the process gas supply controller 90 serving as a gas control structure connected between the first pipe 82 and the second pipe 83. According to the present embodiment, for example, the first pipe 82 extends from an inside of the box housing 73 to an outside of the box housing 73 by passing through the upper surface of the box housing 73 toward the process chamber (not shown). The second pipe 83 from the process gas supply source extends from the outside of the box housing 73 to the inside of the box housing 73 by passing through a bottom surface 77. In addition to the first pipe 82, the second pipe 83 and the process gas supply controller 90, components such as a tank and a vaporizer may be provided in the gas box 140a. The components such as the first pipe 82, the second pipe 83, the process gas supply controller 90, the tank and the vaporizer provided in the gas box 140a may be collectively referred to as the gas supply system.

Conventionally in the substrate processing apparatus 100, a plurality of types of chemical substances are used when the wafer 102 is subject to a heat treatment process. The chemical substances used to process the wafer 102 may be classified into substances such as flammable substances, burnable substances, toxic substances and corrosive substances, and an allowable exposure concentration is set for each of the chemical substances. In general, the first pipe 82 and the second pipe 83 configured to transfer the chemical substances to a heat treatment furnace (that is, the process furnace 103) are made of stainless steel, and are connected using a connector such as a joint. Therefore, the chemical substances may leak from the first pipe 82 or the second pipe 83. Thus, the pipes such as the first pipe 82 and the second pipe 83 are accommodated in the gas box (which is an enclosure) 140a, and an inner atmosphere of the gas box 140a is exhausted to prevent the chemical substances from being exposed to workers when the chemical substances leak. The damper valve 81b is adjusted to reduce an inner pressure of the gas box 140a to a pressure capable of preventing the chemical substances from leaking. The heat is subject to a thermal exhaust when the chemical substances are ventilated through the exhaust duct 81.

A support base 91 is provided in the gas box 140a along an inner wall of a rear plate 76 facing the front panel 75 of the box housing 73. The support base 91 is configured to support components such as the first pipe 82, the second pipe 83 and the process gas supply controller 90. A pipe heater 99 and a heat exchanger 61 are also provided in the gas box 140a.

The process gas supply controller 90 is connected to the first pipe 82 at a downstream end thereof and is connected to the second pipe 83 at an upstream end thereof so as to control a supply flow rate or a supply pressure of the process gas flowing into the first pipe 82. For example, the process gas supply controller 90 is constituted by connecting a flow rate controller (MFC) 92, an air valve 93 and a filter 94 in series from an upstream side to a downstream side of the process gas supply controller 90. Usually, a plurality of configurations including components such as the flow rate controller 92 are provided depending on the number of gas species, the number of nozzles or the number of combinations thereof. That is, a plurality of flow rate controllers including the MFC 92, a plurality of air valves including the air valve 93 and a plurality of filters including the filter 94 may be provided in the gas box 140a. The MFC 92 may include a metal block structure (not shown) in which a flow path is provided and an electric controller (not shown) configured to control and drive a conductance of the flow path.

The pipe heater 99 is configured to heat the first pipe 82, the second pipe 83, the MFC 92, the air valve 93 and the filter 94 of the gas supply system at such locations (heating target) that can be passed through by the vaporized liquid source. It is preferable that the pipe heater 99 can uniformly heat the heating target. An electric heater such as a ribbon heater or a tape heater that can be attached along the flow path may be used as the pipe heater 99. In addition, a heat insulating material (not shown) may be wrapped to cover components such as the MFC 92 and the air valve 93. A temperature of the pipe heater 99 can be elevated to about 180° C. However, a temperature of the heating target is controlled so as to prevent a re-liquefaction of the vaporized liquid source in relation to a vapor pressure. For example, the temperature of the pipe heater 99 is controlled to a temperature ranging from 30° C. to 100° C. The temperature of the heating target may be set such that a temperature of a main path through which the liquid source flows is higher than a temperature of a branch line, and that a temperature of a downstream side of the main path is higher than a temperature of an upstream side of the main path. The heating target may be the metal block structure including the flow path in the MFC 92 and the air valve 93. However, a large amount of heat may be dissipated from the electric controller at which the heat insulating material is not provided. Therefore, the pipe heater 99 may be divided into a plurality of pipe heaters respectively corresponding to different pre-set temperatures or heating amounts of heating targets. In addition, a temperature sensor (not shown) for temperature control may be also provided at the pipe heater 99. In the gas box 140b, such components as a source tank and the vaporizer may also contribute to an increase in the inner temperature of the gas box 140b. These components, together with the pipe heater 99, may be collectively referred to as a “heating element”.

When dry cleaning such components as the process chamber in the process furnace 103, a cleaning gas instead of the vaporized liquid source may be supplied through the first pipe 82 and the second pipe 83 forming the main path of the flow path. When the cleaning gas is supplied, in order to prevent an excessive etching and excessive corrosion of the pipes such as the first pipe 82 and the second pipe 83, the temperature of the pipe heater 99 may be temporarily lowered or the heating by the pipe heater 99 may be stopped. In addition, before lowering the temperature of the pipe heater 99, a purge gas such as nitrogen is circulated in the pipes for a sufficient time to dry and ventilate the inside of the pipes after disconnecting the pipes from the liquid source.

The inlet port 84 is constituted by a plurality of slits (not shown) provided at the lower portion of the front panel 75. A rectifying fin 87 is provided inside the inlet port 84 in parallel with the front panel 75. The rectifying fin 87 is configured to partition a space between the inlet port 84 and the upstream end of the process gas supply controller 90. The space is opened downward, and the rectifying fin 87 switches a flow direction of the air denoted by “a” in FIG. 3 introduced through the inlet port 84 in a downward direction. The air “a” passes through a gap 88 between the rectifying fin 87 and the bottom surface 77, and then flows upward inside the gas box 140a while sufficiently purging the bottom of the gas box 140a. The rectifying fin 87 also prevents a flow (particularly, a flow velocity) passing through the inlet port 84 from being disturbed by an operation of a fan 69 described later.

The heat exchanger 61 serving as a temperature controller is attached to an inner surface of the front panel 75, and is configured to lower an environmental temperature (which is an ambient temperature) of the gas box 140a and to detect and monitor the environmental temperature of the gas box 140a. The environmental temperature may refer to a temperature of the inner atmosphere of the gas box 140a. The heat exchanger 61 is further configured to control an amount of the heat transferred from inside the gas box 140a to the low temperature source outside the gas box 140a. The heat exchanger 61 includes an environmental temperature sensor 62, a heat radiation fin 63, a temperature regulator 64, an inlet port 65, an exhaust port 66 and a fan 67 serving as a first fan (refrigerant fan). The exhaust port 66 is also referred to as an upper vent port, and the inlet port 65 is also referred to as a lower vent port. The environmental temperature sensor 62 is configured to measure a temperature of the air inside the gas box 140a, and is preferably implemented with a thermocouple whose heat capacity is small and whose responsiveness is good. For example, the environmental temperature sensor 62 may be spaced apart appropriately from an object of a particularly high temperature in the gas box 140a. That is, the environmental temperature sensor 62 may be provided in the vicinity of a center of the gas box 140a so as to measure a representative temperature of the air inside the gas box 140a. Alternatively, when a priority is placed on a temperature stabilization of the electric controller in the MFC 92 whose temperature fluctuation most affects a film quality, the environmental temperature sensor 62 may be thermally coupled to the electric controller in the MFC 92.

The heat radiation fin 63 is configured to exchange the heat while fluidically isolating an inside of the gas box 140a from an outside of the gas box 140a. The heat radiation fin 63 is made of a metal material, and includes a large number of folds or turns so as to increase a contact area with the air inside and outside the gas box 140a. That is, an inner side surface (first surface) of the heat radiation fin 63 is exposed in the gas box 140a to be in contact with the air inside the gas box 140a.

The fan 67 is configured to adjust an efficiency of the heat exchange by forming a flow of the air on an outer side surface (second surface) of the heat radiation fin 63 in contact with the air outside the gas box 140a. The inlet port 65 and the exhaust port 66 are openings provided in a housing of the heat radiation fin 63 or the front panel 75, and are configured to allow the air outside the gas box 140a to flow into the heat radiation fin 63. An outside air flow path through which the air outside the gas box 140a flows is formed from the inlet port 65 to the exhaust port 66. A seal such as a packing (not shown) is provided between the front panel 75 and the heat radiation fin 63 so that the inside and the outside of the gas box 140a are not communicated with each other.

The temperature regulator 64 is configured to control a rotation speed of the fan 67 so that the temperature detected by the environmental temperature sensor 62 approaches a predetermined temperature. The fan 67 may be controlled to increase the rotation speed of the fan 67 when the environmental temperature in the gas box 140a is high. On the other hand, the fan 67 may be controlled to stop rotating when the environmental temperature in the gas box 140a is at about room temperature. In addition, the fan 67 is not limited to being attached to the exhaust port 66. For example, the fan 67 may be attached to the inlet port 65. The control of the fan 67 is not limited to a feed-back control. For example, using a relationship between a pre-set temperature of the heating element in the gas box 140a and the environmental temperature, the rotation speed of the fan 67 may be feed-forward controlled. Alternatively, the rotation speed of the fan 67 may be determined by referring to a table storing a relationship between the pre-set temperature of the heating element and the rotation speed of the fan 67. The temperature regulator 64 may be separately provided outside the heat exchanger 61 or the gas box 140a.

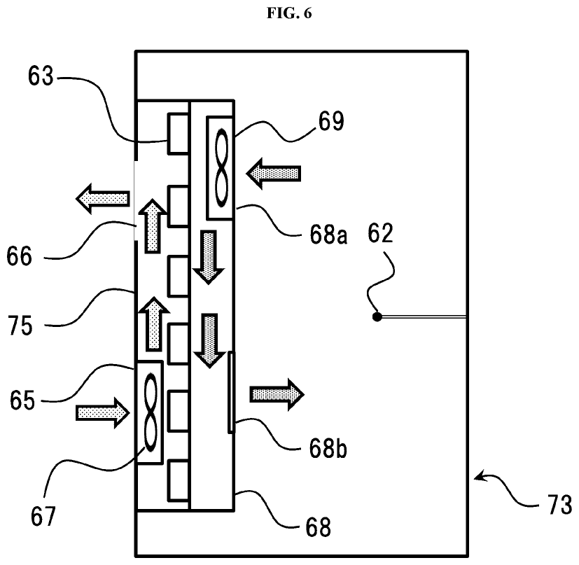

FIG. 6 schematically illustrates an internal configuration of the box housing according to a modified example of the present embodiment. The illustrations of some components such as the process gas supply controller 90 are omitted in FIG. 6 for convenience. The heat exchanger 61 explicitly includes a housing 68, and two chambers partitioned by the heat radiation fin 63 are provided in the housing 68. A room (also referred to as an “outside room”) provided close to the inlet port 65 and the exhaust port 66 is configured so that the air outside the gas box 140a passes through the inlet port 65, the fan 67 and the exhaust port 66. A room (also referred to as an “inside room”) provided close to the center of the gas box 140a is configured so that the air inside the gas box 140a is circulated through an inlet port 68a and an exhaust port 68b provided at the housing 68 by the fan 69 serving as a second fan (circulation fan) provided at the inlet port 68a. When the air inside the gas box 140a is circulated by the fan 69, the housing 68 guides the air so that a flow of the air formed by the fan 69 sufficiently passes through the heat radiation fin 63. The housing 68 is also configured to completely isolate the air inside the gas box 140a from the air outside the gas box 140a in consideration of preventing the gas such as the process gas from being exposed to the workers when the gas leaks.

According to the present embodiment, the pipes are heated so as to prevent the re-liquefaction of the vaporized liquid source caused by passing through the pipes whose temperatures are lowered. When the environmental temperature is too low, a temperature controllability of a heater such as the pipe heater 99 may deteriorate, or the vaporized liquid source may be reliquefied when a temperature of a portion of the pipes is too low. Therefore, when it is desired to maintain an inner temperature of the gas box such as the gas box 140a constant, the temperature regulator 64 desirably controls the rotation speed of the fan 67 or 69 to maintain the inner temperature of the gas box at a certain constant temperature higher than the room temperature.

In addition, it is preferable that the air circulated in the gas box 140a by the fan 69 may sufficiently spread in the gas box 140a after ejected through the exhaust port 68b and before reaching such component as the process gas supply controller 90 serving as the heating target. Thereby, it is possible to prevent components such as the pipes from being locally cooled by low-temperature air ejected through the exhaust port 68b. For example, the exhaust port 68b is provided at a position where the exhaust port 68b does not face the process gas supply controller 90.

Further, in controlling the rotation speed of the fan 69, even when the temperature of the air is constant, a heat radiation amount from the process gas supply controller 90 may fluctuate due to fluctuations in the rotation speed and the temperature. In particular, the temperature of the pipe heater 99 or the electric controller of the MFC 92 (which is not covered with the heat insulating material) may fluctuate. Therefore, the rotation speed of the fan 69 may be maintained constant at a fixed value or a change rate of the rotation speed may be limited to a considerably small value unless the pre-set temperature of the pipe heater 99 is changed. For example, when the temperature regulator 64 is implemented by a digital PID (Proportional-Integral-Differential) controller, a change rate of an output (i.e., operation amount) applied to the fan 69 may be limited to be smaller than that of an output applied to the fan 67. The temperature regulator 64 is communicatively connected to a main controller 131 configured to control the entire substrate processing apparatus 100 so that parameters such as a target temperature can be set.

The gas box 140b is configured similarly to the gas box 140a. Therefore, the detailed descriptions of the gas box 140b are omitted. The exhaust port 81a of the gas box 140b may be provided on a side surface of the gas box 140b. In many cases, the source tank or the vaporizer provided in the gas box 140b may be heated by a large amount of the electric power, and a large amount of heat may be dissipated therefrom. Therefore, without proper cooling, the gas box 140a provided above the gas box 140b may be indirectly heated.

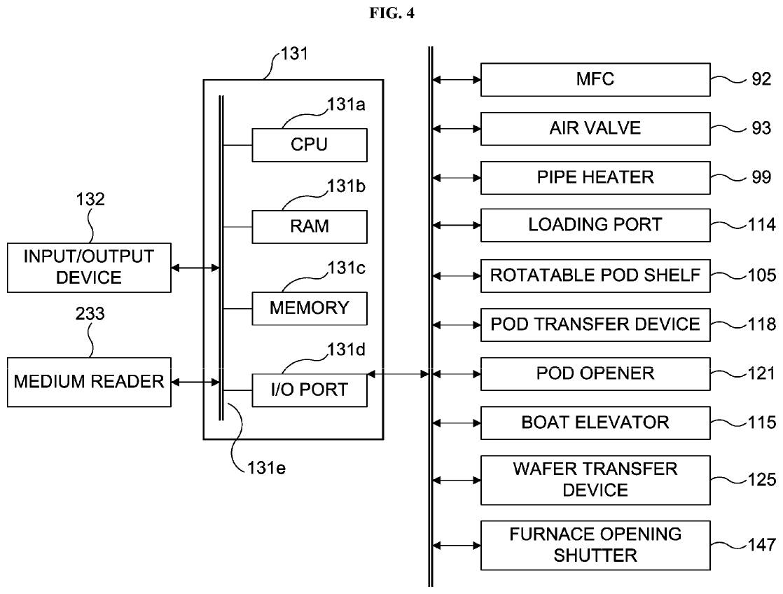

Subsequently, a configuration of the main controller 131 serving as a controller will be described with reference to FIG. 4. The main controller 131 may be embodied by a computer that includes a CPU (central processing unit) 131a, a RAM (Random Access Memory) 131b, a memory 131c and an I/O port 131d. The RAM 131b, the memory 131c and the I/O port 131d may exchange data with the CPU 131a through an internal bus 131e. For example, an input/output device 132 such as a touch panel and a medium reader 233 configured to load a control program described later from an external recording medium are connected to the main controller 131.

The memory 131c may be embodied by components such as a flash memory and a HDD (Hard Disk Drive). Information such as a control program configured to control the operation of the substrate processing apparatus 100 and a process recipe in which information such as the sequences and the conditions of the substrate processing related to a method of manufacturing a semiconductor device is stored may be readably stored in the memory 131c. The process recipe is obtained by combining steps of the substrate processing such that the main controller 131 can execute the steps to acquire a predetermine result, and functions as a program. Hereinafter, the process recipe and the control program may be individually or collectively referred to as a “program”. In the present specification, the term “program” may indicate only the process recipe, may indicate only the control program, or may indicate a combination of the process recipe and the control program. The RAM 131b functions as a memory area (work area) where a program or data read by the CPU 131a is temporarily stored.

The I/O port 131d is configured to operate the above-described components such as the MFC 92, the air valve 93, the pipe heater 99, the loading port 114, the rotatable pod shelf 105, the pod transfer device 118, the pod opener 121, the wafer transfer device 125, the boat elevator 115 and the furnace opening shutter 147 by electric signals.

The CPU 131a is configured to read and execute the control program stored in the memory 131c, and to read the process recipe stored in the memory 131c in accordance with an instruction such as an operation command inputted via the input/output device 132. The CPU 131a is configured to control the operations of the components of the substrate processing apparatus 100 such as the MFC 92, the air valve 93 and the pipe heater 99 in accordance with the process recipe.

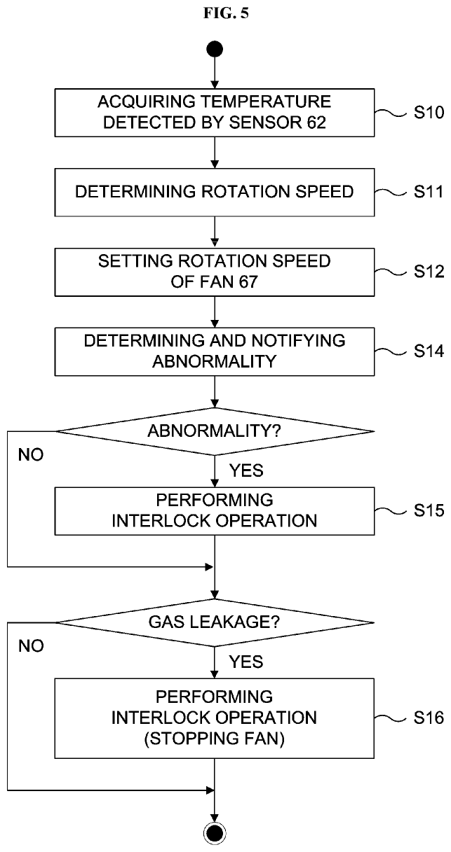

FIG. 5 schematically illustrates an exemplary flow of a temperature control of the gas boxes 140a and 140b by the temperature regulator 64 and the main controller 131. The temperature control of the gas boxes 140a and 140b may be repeatedly and continuously performed while the electric power is supplied to the heating element. That is, the temperature control of the gas boxes 140a and 140b may be started by setting the target temperature by the main controller 131 before the inner temperature of the gas box 140a exceeds the target temperature by supplying the electric power to the heating element.

In a step S10, the temperature regulator 64 acquires the temperature detected by the environmental temperature sensor 62 as a control amount.

In a step S11, the temperature regulator 64 determines the rotation speed. For example, an internal state saved last time is read out, and the internal state is updated based on the read internal state and a difference between the detected temperature in the step S10 and the target temperature. Then, based on the updated internal state, the rotation speed (which is an operation amount) is calculated. According to the present embodiment, the internal state is, for example, an input signal to a differentiator or an output signal of an integrator. PID parameters used to control the fan 67 may be set such that a time constant of the fan 67 is smaller than that of PID parameters of the fan 69.

In a step S12, the temperature regulator 64 sets (that is, determines) the rotation speed of the fan 67. For example, a voltage corresponding to the rotation speed is applied to the fan 67. As a result, the fan 67 is rotated at the determined rotation speed. When the fan 67 is rotated, the outer atmosphere introduced into the gas box 140a through the inlet port 84 is cooled by the heat radiation fin 63 of the heat exchanger 61, and is exhausted to the exhaust duct 81 through the exhaust port 81a.

In a step S14, the temperature regulator 64 notifies the main controller 131 of an error signal when the temperature regulator 64 determines that the control amount or the operation amount is in an abnormal state (that is, an abnormality is detected). Alternatively, the temperature regulator 64 may simply transmit the control amount and the operation amount to the main controller 131, and the main controller 131 may determine that the control amount or the operation amount is in the abnormal state. The abnormal state refers to a state when the control amount is greater than the target temperature by a predetermined value or more or when the operation amount is saturated at a maximum value for a predetermined time or more. In addition, when an actual rotation speed of the fan such as the fan 67 can be detected, the temperature regulator 64 may determine that the control amount or the operation amount is in the abnormal state when the fan is stopped (or fails).

In a step S15, when the abnormality is detected in the step S14, the main controller 131 performs a predetermined interlock operation corresponding to the abnormal state. Specifically, the supply of the gas related to the pipe set to a particularly high temperature or the heating element whose calorific value is large is stopped by operating the air valve 93 or a valve upstream thereof, the purge gas is appropriately circulated in the first pipe 82 and the second pipe 83, and the electric power supplied to the heating element such as the pipe heater 99 is stopped or reduced. When the process recipe of processing the wafer 102 is being performed, the execution of the process recipe is interrupted, and an alarm is issued. The process recipe may be performed again after receiving a confirmation from the operator. When the abnormality is slight, the process recipe may be continued while issuing the alarm. In addition, an abnormal temperature transition and an accumulation of time during which the abnormality lasts may be recorded as a log.

In a step S16, the main controller 131 determines whether the gas sensor 81c detects the leaked gas (that is, whether a gas leakage alarm is issued), and when the leaked gas is detected, a predetermined interlock corresponding to the leaked gas is performed. Specifically, in addition to operating the valve similar to the step S15, the fan 67 is stopped. For example, a pressure deviation in the gas box 140a, which expands due to the operation of the fan 67, may cause an unexpected leakage from the box housing 73. In addition, the stirring by the fan 67 may destroy a diffusion barrier maintained by a uniform flow from the inlet port 84 to the exhaust port 81a, and the gas diffusion toward the inlet port 84 may cause the leakage. To address the problems described above, the fan 67 is stopped. By stopping the fan 67, it is possible to maximize the safety against the gas leakage.

According to the present embodiment, by providing the heat exchanger 61 capable of cooling the inside of the gas box 140a while maintaining the airtightness of the gas box 140a, it is possible to maintain the temperature of the air in the gas box even when the number of the pipes to be heated is increased or when a large object to be heated is placed in the gas box. It is also possible to maintain a productivity of the substrate processing, and to provide the apparatus such as the substrate processing apparatus 100 in which components such as an electric component are not easily damaged. The electric component is not limited to an active component used in the MFC. For example, the electric component may include a wiring cable.

According to the present embodiment, it is possible to increase an upper limit temperature at which components such as the pipes can be heated while maintaining the temperature of the air in the gas box at a predetermined temperature or lower. In other words, it is possible to increase a temperature difference between the objects to be heated (for example, the pipes) and other objects not to be heated (for example, the electric component). When the temperature is elevated, a life of the electric component may be shortened, and the electric component may emit an undesired gas such as an organic gas or a metal such as phosphorus, which may deteriorate a process quality of the wafer.

In addition, according to the present embodiment, it is possible to maintain the inner temperature of the gas box at the predetermined temperature or lower without increasing the exhaust gas to the exhaust duct 81. When exhausting the process gas, it may cost to detoxify the process gas. It may also increase an operating cost when a large amount of the air is supplied to exhaust the process gas. In addition, a large amount of the inert gas may be supplied into the exhaust duct 81 in order to dilute an explosive gas discharged in an emergency to a concentration below a lower explosive limit thereof. If a sufficient capacity of exhausting the gas such as the explosive gas is to be prepared in case of such emergency, it may increase an equipment cost.

In addition, according to the present embodiment, by attaching the heat exchanger 61 to the maintenance door 80 of the front panel 75, it is possible to provide a sufficient cooling capacity of the heat exchanger 61 without increasing the size of the gas box. Since the heat exchanger 61 is air-cooled, the heat exchanger 61 can be connected simply by an electric cable. In addition, the heat exchanger 61 can be easily attached to the maintenance door 80 that is movable, and the fan 67 can be easily replaced.

### Other Embodiments

While the technique is described in detail by way of the above-described embodiment and the modified example, the above-described technique is not limited thereto. The above-described technique may be modified in various ways without departing from the scope thereof.

For example, while the embodiment and the modified example are described by way of an example in which the process gas supply controller 90 is interconnected to components such as the MFC 92 by individual pipes, the above-described technique is not limited thereto. For example, the process gas supply controller 90 may be implemented using an integrated gas system. When the process gas supply controller 90 is implemented using the integrated gas system, the heating by the pipe heater is performed in units of a base block. The flow path may be formed by placing components on the base block and connecting the components directly or via the pipes. In addition, a gap through which the air flows may be provided between adjacent MFCs to prevent an overheating of an electric circuit such as the electric component.

According to some embodiments in the present disclosure, it is possible to prevent the deterioration in controllability of the gas flow rate in the substrate processing apparatus.

What is claimed is:

1. A substrate processing apparatus comprising:
a process furnace comprising a process chamber in which a substrate is processed;
a process gas supply path configured to supply a process gas of processing the substrate into the process chamber;
a process gas supply controller configured to control an amount of the process gas supplied into the process chamber;
a heater configured to heat at least a part of the process gas supply controller or the process gas supply path; and
a gas box configured to accommodate the process gas supply path, the process gas supply controller and the heater, wherein the gas box comprises:
an inlet port configured to introduce an outer atmosphere of the gas box into the gas box;
an exhaust port connected to an exhaust duct and configured to exhaust an inner atmosphere of the gas box to the exhaust duct;
a temperature controller configured to cool the inner atmosphere of the gas box and to detect and monitor a temperature of the inner atmosphere of the gas box; and
a gas leakage sensor configured to detect the process gas leaked in the gas box.

2. The substrate processing apparatus of claim 1, wherein the temperature controller is further configured to control an amount of heat transferred from inside the gas box to a low temperature source outside the gas box.

3. The substrate processing apparatus of claim 2, wherein the temperature controller is provided inside the gas box, and further configured to: use an air outside the gas box as the low temperature source; communicate with an upper vent port and a lower vent port provided in the gas box; and be in contact with a space in which the process gas supply controller is provided and from which an outside air flow path is isolated, and
wherein a refrigerant fan is provided in the outside air flow path.

4. The substrate processing apparatus of claim 3, wherein the temperature controller further comprises a circulation fan configured to form a flow of the inner atmosphere of the gas box in the space.

5. The substrate processing apparatus of claim 4, wherein the circulation fan is stopped when the gas leakage sensor detects the process gas leaked into the gas box.

6. The substrate processing apparatus of claim 3, wherein the heat exchanger is provided on an opening/closing door of the gas box.

7. The substrate processing apparatus of claim 1, wherein the process gas supply controller comprises a plurality of mass flow controllers, and
wherein the heater is configured to heat a mass flow controller through which a vaporized liquid source passes among the plurality of the mass flow controllers to a temperature capable of preventing a re-liquefaction of the vaporized liquid source.

8. The substrate processing apparatus of claim 7, wherein the heater is configured to heat a metal block structure including a flow path of the mass flow controller through which the vaporized liquid source passes.

9. The substrate processing apparatus of claim 8, wherein the metal block structure is covered with a heat insulating material.

10. The substrate processing apparatus of claim 1, wherein the temperature controller comprises:
a heat radiation fin whose first surface is in contact with the inner atmosphere of the gas box and whose second surface is in contact with the outer atmosphere of the gas box;
a first fan configured to form a flow of the outer atmosphere of the gas box on the second surface;
a temperature sensor configured to measure an inner temperature of the gas box; and
a temperature regulator configured to control a rotation speed of the first fan based on the inner temperature of the gas box measured by the temperature sensor.

11. The substrate processing apparatus of claim 10, wherein the temperature sensor configured to measure a representative temperature of an air inside the gas box as the inner temperature of the gas box.

12. The substrate processing apparatus of claim 10, wherein the process gas supply controller comprises a plurality of mass flow controllers, and
wherein the temperature sensor is thermally coupled to an electric controller in a mass flow controller among the plurality of the mass flow controllers.

13. The substrate processing apparatus of claim 10, wherein the temperature controller further comprises a second fan configured to form a flow of the inner atmosphere of the gas box on the first surface, and
wherein a rotation speed of the second fan is a fixed value determined by a pre-set temperature of the heater.

14. The substrate processing apparatus of claim 10, wherein the temperature controller further comprises a second fan configured to form a flow of the inner atmosphere of the gas box on the first surface, and
wherein the temperature regulator is further configured to control a rotation speed of the second fan.

15. The substrate processing apparatus of claim 14, wherein the temperature regulator is further configured to limit a change rate of an operation amount applied to the second fan to be smaller than that of an operation amount applied to the first fan.

16. A gas box provided in a substrate processing apparatus, the gas box comprising:
a housing configured to accommodate:
a process gas supply path configured to supply a process gas of processing a substrate into the process chamber;
a process gas supply controller configured to control an amount of the process gas supplied into the process chamber; and
a heater configured to heat at least a part of the process gas supply controller or the process gas supply path;
an inlet port configured to introduce an outer atmosphere of the gas box into the gas box;
an exhaust port connected to an exhaust duct and configured to exhaust an inner atmosphere of the gas box to the exhaust duct;
a temperature controller configured to cool the inner atmosphere of the gas box and to detect or monitor a temperature of the inner atmosphere of the gas box; and
a gas leakage sensor configured to detect the process gas leaked into the gas box.
